(19) United States
(12) Patent Application Publication
(10) Pub. No.: US 2024/0145396 A1
(43) Pub. Date: May 2, 2024

(54) SEMICONDUCTOR PACKAGE AND METHOD OF MANUFACTURING THE SAME

(71) Applicant: SAMSUNG ELECTRONICS CO., LTD., SUWON-SI (KR)

(72) Inventors: Sehoon JANG, Suwon-si (KR); Hyeonjeong HWANG, Suwon-si (KR); Kyounglim SUK, Suwon-si (KR)

(21) Appl. No.: 18/381,711

(22) Filed: Oct. 19, 2023

(30) Foreign Application Priority Data
Oct. 31, 2022 (KR) 10-2022-0143022

(51) Int. Cl. H01L 23/538; H01L 21/48; H01L 21/56; H01L 23/31; H01L 25/18; H10B 80/00

(52) U.S. Cl. CPC H01L 23/5386; H01L 21/4857; H01L 21/568; H01L 23/3128; H01L 23/5385; H01L 25/18; H10B 80/00; H01L 24/16

(57) ABSTRACT

A semiconductor package includes a base substrate. An interposer substrate includes a plurality of interposer redistribution structures sequentially stacked in a vertical direction and an interposer insulation layer. The plurality of interposer redistribution structures includes a plurality of conductive interposer patterns and a plurality of conductive interposer vias. A semiconductor chip is disposed between the base substrate and the interposer substrate and is attached on the base substrate. A plurality of conductive connection pads is respectively disposed on a plurality of uppermost conductive interposer patterns of an uppermost interposer redistribution structure of the plurality of interposer redistribution structures. The interposer insulation layer includes a plurality of pad holes exposing at least a portion of each of an upper surface of a corresponding uppermost conductive interposer pattern of the plurality of uppermost conductive interposer patterns.

### CROSS-REFERENCE TO RELATED APPLICATION

This application claims priority under 35 U.S.C. § 119 to korean Patent Application No. 10-2022-0143022, filed on Oct. 31, 2022 in the Korean Intellectual Property Office, the disclosure of which is incorporated by reference in its entirety herein.

### 1. TECHNICAL FIELD

The present disclosure relates to a semiconductor package and a method of manufacturing the same, and more particularly, to a fan-out semiconductor package and a method of manufacturing the same.

### 2. DISCUSSION OF RELATED ART

Electronic devices have become increasingly miniaturized and light as the electronics industry advances and the demands of users increase. Therefore, the demand for semiconductor chips that are applied to electronic devices to have a high integration level has increased. To respond to such a trend, research is being conducted concerning several semiconductor packages that are stacked on one package substrate, or a semiconductor package structure in which an interposer substrate is inserted between semiconductor chips. Furthermore, research is being conducted concerning a stack-type semiconductor package structure in which a second semiconductor package structure is stacked on a semiconductor package structure.

### SUMMARY

Embodiments of the present disclosure provide a semiconductor package having increased reliability.

Embodiments of the present disclosure provide a method of manufacturing a semiconductor package having increased reliability.

According to an embodiment of the present disclosure, a semiconductor package includes a base substrate. An interposer substrate includes a plurality of interposer redistribution structures sequentially stacked in a vertical direction and an interposer insulation layer. The plurality of interposer redistribution structures includes a plurality of conductive interposer patterns and a plurality of conductive interposer vias. A semiconductor chip is disposed between the base substrate and the interposer substrate in the vertical direction and attached on the base substrate. A plurality of conductive connection pads is respectively disposed on a plurality of uppermost conductive interposer patterns of an uppermost interposer redistribution structure of the plurality of interposer redistribution structures. The interposer insulation layer comprises a plurality of pad holes. Each pad hole of the plurality of pad holes exposes at least a portion of each of an upper surface of a corresponding conductive connection pad of the plurality of conductive connection pads and an upper surface of a corresponding uppermost conductive interposer pattern of the plurality of uppermost conductive interposer patterns. A side surface of each of the plurality of conductive connection pads is vertical to an upper surface of the interposer insulation layer. A side surface of each of the plurality of uppermost conductive interposer patterns is vertical to the upper surface of the interposer insulation layer. An inner sidewall of each of the plurality of pad holes is inclined with respect to the upper surface of the interposer insulation layer.

According to an embodiment of the present disclosure, a semiconductor package includes a base substrate having a plurality of base redistribution structures sequentially stacked in a vertical direction and a base insulation layer. The plurality of base redistribution structures includes a plurality of conductive base patterns and a plurality of conductive base vias. A semiconductor chip is attached on the base substrate by a plurality of chip connection members. An interposer substrate includes a plurality of interposer redistribution structures sequentially stacked in the vertical direction and an interposer insulation layer having an upper surface that includes a plurality of pad holes. The interposer substrate is disposed on the semiconductor chip. The plurality of interposer redistribution structures includes a plurality of conductive interposer patterns and a plurality of conductive interposer vias. A plurality of conductive posts is disposed around the semiconductor chip to extend in the vertical direction. The plurality of conductive posts connects the base substrate with the interposer substrate. A molding layer is disposed between the base substrate and the interposer substrate. The molding layer surrounds the semiconductor chip and the plurality of conductive posts. A plurality of conductive connection pads is respectively disposed on a plurality of uppermost conductive interposer patterns of an uppermost interposer redistribution structure of the plurality of interposer redistribution structures and is respectively disposed in the plurality of pad holes. A plurality of conductive pad seed layers respectively disposed between a corresponding uppermost conductive interposer pattern of the plurality of uppermost conductive interposer patterns and a corresponding conductive connection pad of the plurality of conductive connection pads. The plurality of conductive pad seed layers respectively covering lower surfaces of the plurality of conductive connection pads. A side surface and an upper surface of each of the plurality of uppermost conductive interposer patterns and a side surface and an upper surface of each of the plurality of conductive connection pads are exposed by the interposer insulation layer.

According to an embodiment, a semiconductor package includes a first base substrate. A first semiconductor chip is attached on the first base substrate. A plurality of conductive posts is disposed around the first semiconductor chip, on the first base substrate. An interposer substrate includes an interposer redistribution structure having a conductive interposer pattern, a conductive interposer via and an interposer insulation layer. The interposer insulation layer has an upper surface including a pad hole exposing the conductive interposer pattern. The interposer substrate is electrically connected with the first base substrate through the plurality of conductive posts. A second base substrate is on the interposer substrate. A second semiconductor chip is attached on the second base substrate. A conductive connection pad is disposed on the conductive interposer pattern, in the pad hole. An external connection terminal is disposed on the conductive connection pad. The external connection terminal electrically connecting the interposer substrate with the second base substrate. An inner sidewall of the pad hole is inclined with respect to an upper surface of the interposer insulation layer. The inner sidewall of the pad hole is spaced apart from the conductive connection pad and the conductive interposer pattern in a first horizontal direction.

### BRIEF DESCRIPTION OF THE DRAWINGS

Embodiments of the present disclosure will be more clearly understood from the following detailed description taken in conjunction with the accompanying drawings in which:

FIG. 1 is a cross-sectional view illustrating a semiconductor package according to an embodiment of the present disclosure;

FIG. 2 is an enlarged view of a region EX1 of FIG. 1 according to an embodiment of the present disclosure;

FIG. 3 is an enlarged view of a region EX2 of FIG. 1 according to an embodiment of the present disclosure;

FIGS. 4 and 5 are schematic plan views for describing some elements of the region EX2 of FIG. 1, in a semiconductor package according to embodiments of the present disclosure;

FIG. 6 is an enlarged view of a region corresponding to the region EX2 of FIG. 1, in a semiconductor package according to an embodiment of the present disclosure;

FIG. 7 is a cross-sectional view illustrating a package-on-package type semiconductor package in which an upper package is stacked on a lower package, in a semiconductor package according to an embodiment of the present disclosure;

FIG. 8 is an enlarged view of a region EX3 of FIG. 7 according to an embodiment of the present disclosure;

FIG. 9 is an enlarged view of the region EX3 of FIG. 7, in a package-on-package type semiconductor package according to an embodiment of the present disclosure; and

FIGS. 10A to 10L are cross-sectional views illustrating a method of manufacturing a semiconductor package in sequence, according to embodiments of the present disclosure.

### DETAILED DESCRIPTION OF EMBODIMENTS

Hereinafter, embodiments of the present disclosure will be described in detail with reference to the accompanying drawings. Like reference numerals refer to like elements in the drawings, and their repeated descriptions are omitted.

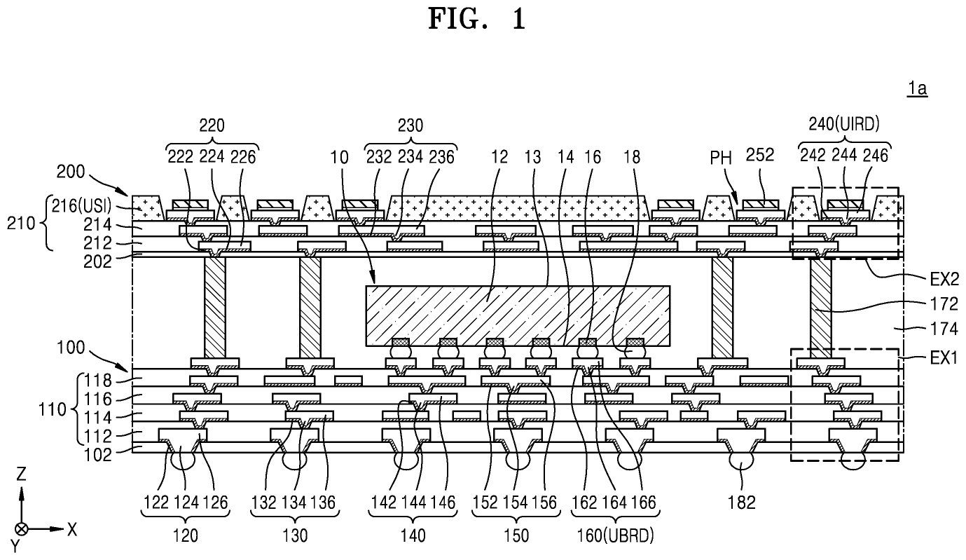

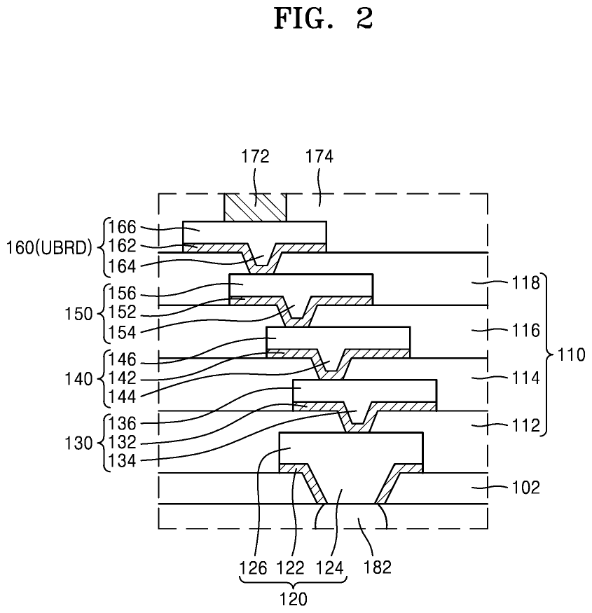

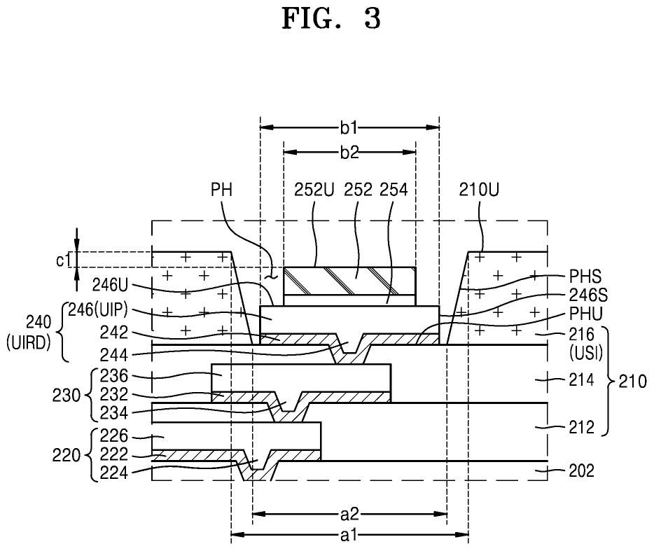

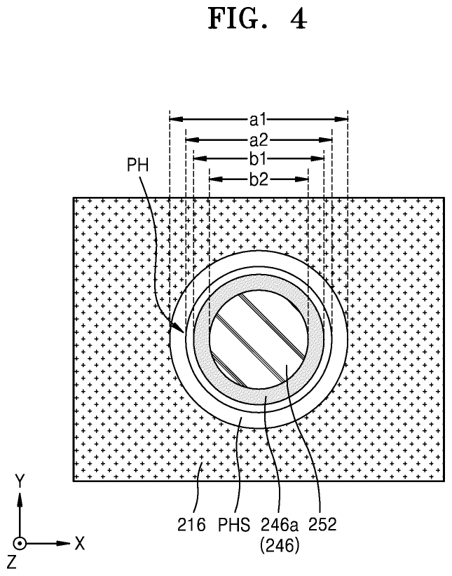

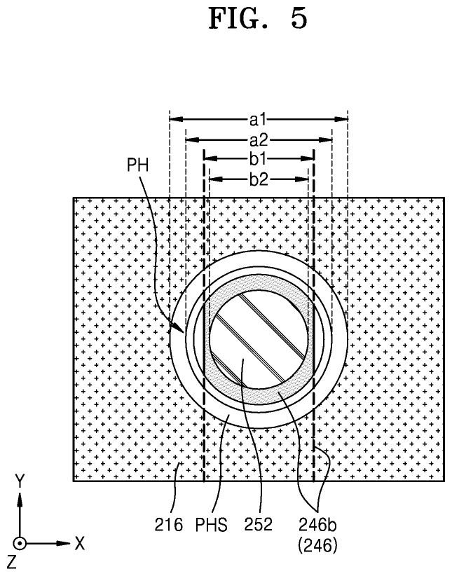

FIG. 1 is a cross-sectional view illustrating a semiconductor package 1a according to an embodiment. FIG. 2 is an enlarged view of a region EX1 of FIG. 1. FIG. 3 is an enlarged view of a region EX2 of FIG. 1, and FIGS. 4 and 5 are schematic plan views for describing some elements of the region EX2 of FIG. 1, in the semiconductor package 1a according to embodiments.

Referring to FIGS. 1 to 3, the semiconductor package 1a may include a base substrate 100, a semiconductor chip 10 on the base substrate 100, and an interposer substrate 200 covering the semiconductor chip 10.

As the miniaturization of semiconductor chips or the number of input/output terminals thereof increases, there may be a limitation in accommodating all input/output terminals into a main surface of a semiconductor chip. The semiconductor package 1a according to embodiments may be a fan-out package in which an input/output terminal is disposed to extend up to an outer region of an outer perimeter surface of the semiconductor chip 10. Furthermore, the semiconductor package 1a may be a fan-out wafer level package (FOWLP) or a fan-out panel level package (FOPLP), which is manufactured at a wafer level or a panel level.

According to an embodiment, the base substrate 100 may include a first lower insulation layer 102, a base insulation layer 110, and a plurality of base redistribution structures 120 to 160 arranged at different levels in a vertical direction (e.g., the Z direction).

In an embodiments the base insulation layer 110 may include first to fourth sub base insulation layers 112, 114, 116, and 118 which are sequentially stacked on the first lower insulation layer 102 (e.g., in the Z direction). In FIG. 1, the base insulation layer 110 is illustrated as including four sub base insulation layers. However, embodiments of the present disclosure are not necessarily limited thereto. For example, in some embodiments the base insulation layer 110 may include one, two, or three sub base insulation layers, or may include five or more sub base insulation layers. According to an embodiment, the base insulation layer 110 may be provided in an integrated structure. For example, the first to fourth sub base insulation layers 112, 114, 116, and 118 may be provided in an integrated structure. For example, an upper surface of the fourth sub base insulation layer 118 may be an upper surface of the base insulation layer 110. According to an embodiment, the base insulation layer 110 and the first lower insulation layer 102 may be provided in an integrated structure.

According to an embodiment, each of the first lower insulation layer 102 and the first to fourth sub base insulation layers 112, 114, 116, and 118 may include an organic polymer material. According to an embodiment, each of the first lower insulation layer 102 and the first to fourth sub base insulation layers 112, 114, 116, and 118 may include a photo imageable dielectric (PID) capable of a photoresist process.

According to an embodiment, the first to fifth base redistribution structures 120 to 160 may be sequentially stacked in the vertical direction (e.g., the Z direction) on the first lower insulation layer 102 and may be at least partially surrounded by the first lower insulation layer 102 and the first to fourth sub base insulation layers 112, 114, 116, and 118.

In FIG. 1, the base substrate 100 is illustrated as including five base redistribution structures, but is not limited thereto. For example, the base substrate 100 may include two, three, or four base redistribution structures which are sequentially stacked, or may include six or more base redistribution structures which are sequentially stacked.

According to an embodiment, the first base redistribution structure 120 may be a lowermost base redistribution structure of the base substrate 100 (e.g., in the Z direction). According to an embodiment, the first base redistribution structure 120 may include a plurality of first conductive base seed layers 122, a plurality of first conductive base pads 124, and a plurality of first conductive base patterns 126. According to an embodiment, the plurality of first conductive base patterns 126 may be disposed on an upper surface of the first lower insulation layer 102 to extend in a horizontal direction (e.g., an X direction and/or a Y direction) and may be connected with the plurality of first conductive base pads 124 passing through the first lower insulation layer 102 in the vertical direction (e.g., the Z direction). In this embodiment, a lower surface of each of the plurality of first conductive base pads 124 may be exposed at a lower surface of the first lower insulation layer 102.

According to an embodiment, the first sub base insulation layer 112 on the first lower insulation layer 102 may surround the plurality of first conductive base patterns 126. According to an embodiment, the plurality of first conductive base seed layers 122 may include a portion disposed between the plurality of first conductive base patterns 126 and the first lower insulation layer 102 and a portion disposed between the plurality of first conductive base pads 124 and the first lower insulation layer 102. In some embodiments, each of the plurality of first conductive base patterns 126 and a corresponding first conductive base pad 124 connected thereto may be provided in an integrated structure. However, embodiments of the present disclosure are not necessarily limited thereto.

In some embodiments, a lower surface of each of the plurality of first conductive base pads 124 may be disposed at the same level as a lower surface of the first lower insulation layer 102 in the vertical direction (e.g., the Z direction). However, embodiments of the present disclosure are not necessarily limited thereto. For example, in some embodiments, the lower surface of each of the plurality of first conductive base pads 124 may not be disposed at the same level as the lower surface of the first lower insulation layer 102 in the vertical direction (e.g., the Z direction). For example, in an embodiment the lower surface of each of the plurality of first conductive base pads 124 may be disposed at a level that is higher than the lower surface of the first lower insulation layer 102 in the vertical direction (e.g., the Z direction). In an embodiment, the lower surface of each of the plurality of first conductive base pads 124 may be disposed at a level that is lower than the lower surface of the first lower insulation layer 102 in the vertical direction (e.g., the Z direction).

According to an embodiment, a plurality of external connection terminals 182 may be respectively disposed on the lower surfaces of the plurality of first conductive base pads 124. According to an embodiment, the semiconductor package 1a may be configured to be electrically connected with a motherboard or the other external devices. For example, in an embodiment each of the plurality of first conductive base pads 124 may function as an under bump metallurgy (UBM). For example, each of the plurality of external connection terminals 182 may be a solder ball or a bump. However, embodiments of the present disclosure are not necessarily limited thereto.

According to an embodiment, the second base redistribution structure 130 may be disposed on the first base redistribution structure 120 (e.g., in the Z direction). According to an embodiment, the second base redistribution structure 130 may include a plurality of second conductive base seed layers 132, a plurality of second conductive base vias 134, and a plurality of second conductive base patterns 136. According to an embodiment, the plurality of second conductive base patterns 136 may extend in the horizontal direction (e.g., the X direction and/or the Y direction) on an upper surface of the first sub base insulation layer 112 and may be surrounded by the second sub base insulation layer 114. According to an embodiment, each of the plurality of second conductive base vias 134 may pass through the first sub base insulation layer 112 in the vertical direction (e.g., the Z direction) on the first conductive base pattern 126 and may connect the first conductive base pattern 126 with the second conductive base pattern 136. According to an embodiment, each of the plurality of second conductive base seed layers 132 may include a portion disposed between the second conductive base pattern 136 and the first sub base insulation layer 112, a portion between the plurality of second conductive base vias 134 and the first sub base insulation layer 112, and a portion disposed between the plurality of second conductive base vias 134 and the plurality of first conductive base patterns 126. According to an embodiment, each of the plurality of first conductive base patterns 126 and a corresponding second conductive base via 134 connected thereto may be provided in an integrated structure.

According to an embodiment, the third base redistribution structure 140 may be disposed on the second base redistribution structure 130 (e.g., in the Z direction). According to an embodiment, the third base redistribution structure 140 may include a plurality of third conductive base seed layers 142, a plurality of third conductive base vias 144, and a plurality of third conductive base patterns 146. According to an embodiment, the plurality of third conductive base patterns 146 may extend in the horizontal direction (e.g., the X direction and/or the Y direction) on an upper surface of the second sub base insulation layer 114 and may be surrounded by the third sub base insulation layer 116. According to an embodiment, each of the plurality of third conductive base vias 144 may pass through the second sub base insulation layer 114 in the vertical direction (e.g., the Z direction) on the second conductive base pattern 136 and may connect the second conductive base pattern 136 with the third conductive base pattern 146. According to an embodiment, each of the plurality of third conductive base seed layers 142 may include a portion disposed between the third conductive base pattern 146 and the second sub base insulation layer 114, a portion between the plurality of third conductive base vias 144 and the second sub base insulation layer 114, and a portion disposed between the plurality of third conductive base vias 144 and the plurality of second conductive base patterns 136. According to an embodiment, each of the plurality of third conductive base patterns 146 and a corresponding third conductive base via 144 connected thereto may be provided in an integrated structure.

According to an embodiment, the fourth base redistribution structure 150 may be disposed on the third base redistribution structure 140 (e.g., in the Z direction). According to an embodiment, the fourth base redistribution structure 150 may include a plurality of fourth conductive base seed layers 152, a plurality of fourth conductive base vias 154, and a plurality of fourth conductive base patterns 156. According to an embodiment, the plurality of fourth conductive base patterns 156 may extend in the horizontal direction (e.g., the X direction and/or the Y direction) on an upper surface of the third sub base insulation layer 116 and may be surrounded by the fourth sub base insulation layer 118. According to an embodiment, each of the plurality of fourth conductive base vias 154 may pass through the third sub base insulation layer 116 in the vertical direction (e.g., the Z direction) on the third conductive base pattern 146 and may connect the third conductive base pattern 146 with the fourth conductive base pattern 156. According to an embodiment, each of the plurality of fourth conductive base seed layers 152 may include a portion disposed between the fourth conductive base pattern 156 and the third sub base insulation layer 116, a portion between the plurality of fourth conductive base vias 154 and the third sub base insulation layer 116, and a portion disposed between the plurality of fourth conductive base vias 154 and the plurality of third conductive base patterns 146. According to an embodiment, each of the plurality of fourth conductive base patterns 156 and a corresponding fourth conductive base via 154 connected thereto may be provided in an integrated structure.

According to an embodiment, the fifth base redistribution structure 160 may be disposed on the fourth base redistribution structure 150. According to an embodiment, the fifth base redistribution structure 160 may correspond to a base redistribution structure that is disposed uppermost in the vertical direction (e.g., the Z direction) among the first to fifth base redistribution structures 120 to 160. For example, the fifth base redistribution structure 160 may be an uppermost base redistribution structure (UBRD).

According to an embodiment, the fifth base redistribution structure 160 may include a plurality of fifth conductive base seed layers 162, a plurality of fifth conductive base vias 164, and a plurality of fifth conductive base patterns 166. According to an embodiment, the plurality of fifth conductive base patterns 166 may include a base redistribution line that extends in the horizontal direction (e.g., the X direction and/or the Y direction) on an upper surface of the fourth sub base insulation layer 118, and a base redistribution pad that is configured to connect the base substrate 100 with the semiconductor chip 10. According to an embodiment, each of the plurality of fifth conductive base vias 164 may pass through the fourth sub base insulation layer 118 in the vertical direction (e.g., the Z direction) on the fourth conductive base pattern 156 and may connect the fourth conductive base pattern 156 with the fourth conductive base pattern 166. According to an embodiment, each of the plurality of fifth conductive base seed layers 162 may include a portion disposed between the fifth conductive base pattern 166 and the fourth sub base insulation layer 118, a portion between the plurality of fifth conductive base vias 164 and the fourth sub base insulation layer 118, and a portion disposed between the plurality of fifth conductive base vias 164 and the plurality of fourth conductive base patterns 156. According to an embodiment, each of the plurality of fifth conductive base patterns 166 and a corresponding fifth conductive base via 164 connected thereto may be provided in an integrated structure.

According to an embodiment, the plurality of first to fifth conductive base seed layers 122, 132, 142, 152, and 162 may each include copper (Cu), titanium (Ti), titanium tungsten (TiW), titanium nitride (TiN), tantalum (Ta), tantalum nitride (TaN), chromium (Cr), aluminum (Al), or a combination thereof. However, embodiments of the present disclosure are not necessarily limited thereto. According to an embodiment, the plurality of first to fifth conductive base seed layers 122, 132, 142, 152, and 162 may each include Cu/Ti in which copper is stacked on titanium or Cu/TiW in which copper is stacked on titanium tungsten.

According to an embodiment, the plurality of first conductive base pads 124 may include metal, such as copper (Cu), aluminum (Al), tungsten (W), titanium (Ti), tantalum (Ta), indium (In), molybdenum (Mo), manganese (Mn), cobalt (Co), zinc (Sn), nickel (Ni), magnesium (Mg), rhenium (Re), beryllium (Be), gallium (Ga), or ruthenium (Ru), or an alloy thereof.

According to an embodiment, the plurality of second to fifth conductive base vias 134, 144, 154, and 164 and the plurality of first to fifth conductive base patterns 126, 136, 146, 156, and 166 may each include metal, such as copper (Cu), aluminum (Al), tungsten (W), titanium (Ti), tantalum (Ta), indium (In), molybdenum (Mo), manganese (Mn), cobalt (Co), zinc (Sn), nickel (Ni), magnesium (Mg), rhenium (Re), beryllium (Be), gallium (Ga), or ruthenium (Ru), or an alloy thereof.

According to an embodiment, the semiconductor chip 10 may include an active surface 14 and an inactive surface 13, which are opposite to each other (e.g., in the Z direction), and a semiconductor substrate 12. The semiconductor chip 10 includes a semiconductor device including an integrated circuit. According to an embodiment, a circuit unit for implementing an integrated circuit function of the semiconductor chip 10 may be provided on the active surface 14 of the semiconductor substrate 12. According to an embodiment, a plurality of chip pads 16 may be disposed on a lower surface of the semiconductor chip 10 adjacent to the active surface 14 of the semiconductor substrate 12. In an embodiment, the active surface 14 of the semiconductor substrate 12 may have a close proximity to the lower surface of the semiconductor chip 10, and thus, it is not illustrated that the active surface 14 of the semiconductor substrate 12 is separately differentiated from the lower surface of the semiconductor chip 10. For example, the lower surface of the semiconductor chip 10 (e.g., in the Z direction) may be referred to as the active surface 14 of the semiconductor substrate 12, and an upper surface of the semiconductor chip 10 (e.g., in the Z direction) may be referred to as the inactive surface 13 of the semiconductor substrate 12.

According to an embodiment, the semiconductor chip 10 may have face-down arrangement in which the active surface 14 of the semiconductor substrate 12 faces the base substrate 100 and may be disposed on the base substrate 100.

According to an embodiment, the semiconductor chip 10 may include a plurality of chip pads 16 and may be connected with the base substrate 100 through a plurality of chip connection members 18 between some of the plurality of fifth conductive base patterns 166 and the plurality of chip pads 16. In this embodiment, the plurality of fifth conductive base patterns 166 connected with the plurality of chip connection members 18 may perform a function of a conductive pad.

For example, in an embodiment each of the plurality of chip connection members 18 may include a solder ball or a micro-bump. However, embodiments of the present disclosure are not necessarily limited thereto.

According to an embodiment, the semiconductor substrate 12 may include, for example, a semiconductor material, such as silicon (Si) or germanium (Ge). According to an embodiment, the semiconductor substrate 12 may include, for example, a compound semiconductor material, such as silicon carbide (SiC), gallium arsenide (GaAs), indium arsenide (InAs), or indium phosphide (InP). For example, the semiconductor substrate 12 may include a conductive region (for example, an impurity-doped well) and may have various device isolation structures, such as a shallow trench isolation (STI) structure.

In some embodiments, the semiconductor chip 10 may be a logic chip. For example, the semiconductor chip 10 may be a central processing unit (CPU) chip, a graphics processing unit (GPU) chip, or an application processor (AP) chip. In some embodiments, the semiconductor chip 10 may be a memory semiconductor chip. For example, the semiconductor chip 10 may be a non-volatile memory semiconductor chip, such as flash memory, phase-change random access memory (PRAM), magnetoresistive random access memory (MRAM), ferroelectric random access memory (FeRAM), or resistive random access memory (RRAM). In an embodiment, the flash memory may be, for example, NAND flash memory or V-NAND flash memory. For example, the semiconductor chip 10 may be a volatile memory semiconductor chip, such as dynamic random access memory (DRAM) or static random access memory (SRAM).

According to an embodiment, a plurality of conductive posts 172 may be disposed around the semiconductor substrate 12. According to an embodiment, the plurality of conductive posts 172 may be disposed on some of the plurality of fifth conductive base patterns 166 and may be configured to electrically connect the base substrate 100 with the interposer substrate 200. In this embodiment, the plurality of fifth conductive base patterns 166 connected with the plurality of conductive posts 172 may function as a conductive pad. According to an embodiment, the plurality of conductive posts 172 may include Cu, Cu—Sn (CuSn), Cu—Mg (CuMg), Cu—Ni (CuNi), Cu—Zn (CuZn), copper-lead (CuPd), Cu—W (CuW), W, or an alloy thereof. However, embodiments of the present disclosure are not necessarily limited thereto.

According to an embodiment, a molding layer 174 may be disposed in a space between the base substrate 100 and the interposer substrate 200. The molding layer 174 may surround the semiconductor chip 10, the plurality of conductive posts 172, the plurality of fifth conductive base patterns 166, and the plurality of chip connection members 18. For example, an uppermost conductive base pattern (e.g., the fifth conductive base pattern 166) of the uppermost base redistribution structure (UBRD) may be disposed on an upper surface of the base insulation layer 110, and a side surface and an upper surface thereof may be covered by the molding layer 174. According to an embodiment, the uppermost conductive base pattern may include epoxy-based mold resin, or polyimide-based mold resin. For example, the uppermost conductive base pattern may be a molding member including an epoxy mold compound (EMC).

According to an embodiment, the interposer substrate 200 may include a second lower insulation layer 202, an interposer insulation layer 210, and a plurality of interposer redistribution structures 220 to 240 arranged at different levels in the vertical direction (e.g., the Z direction).

According to an embodiment, the interposer insulation layer 210 may include first to third sub interposer insulation layers 212, 214, and 216 that are sequentially stacked on the second lower insulation layer 202 (e.g., in the Z direction). In FIG. 1, the interposer insulation layer 210 is illustrated as including three sub interposer insulation layers. However, embodiments of the present disclosure are not necessarily limited thereto. For example, in some embodiments the interposer insulation layer 210 may include one or two sub interposer insulation layers, or may include four or more sub interposer insulation layers. According to an embodiment, the interposer insulation layer 210 may be provided in an integrated structure. For example, the first to third sub interposer insulation layers 212, 214, and 216 may be provided in an integrated structure. For example, an upper surface 210U of the interposer insulation layer 210 may be an upper surface of an uppermost sub interposer insulation layer USI (e.g., the third interposer insulation layer 216) of a plurality of sub interposer insulation layers. According to an embodiment, the interposer insulation layer 210 and the second lower insulation layer 202 may be provided in an integrated structure.

According to an embodiment, each of the second lower insulation layer 202 and the first to third sub interposer insulation layers 212, 214, and 216 may include an organic polymer material. According to an embodiment, each of the second lower insulation layer 202 and the first to third sub interposer insulation layers 212, 214, and 216 may include a PLD capable of a photoresist process.

According to an embodiment, the interposer insulation layer 210 may include a plurality of pad holes PH partially passing through the interposer insulation layer 210 in the upper surface 210U thereof. According to an embodiment, each of the plurality of pad holes PH may include an inlet in the upper surface 210U of the interposer insulation layer 210 and may include a bottom surface PHU and an inner sidewall PHS in the interposer insulation layer 210. According to an embodiment, each of the plurality of pad holes PH may have a tapered shape in which a horizontal cross-sectional area thereof narrows progressively toward the bottom surface PHU thereof from the inlet thereof. In this embodiment, the inner sidewall PHS of each of the plurality of pad holes PH may be inclined with respect to an extending direction of the upper surface 210U of the interposer insulation layer 210. For example, a first width a1 (FIG. 3) that is a width of the inlet of plurality of pad holes PH in a first horizontal direction (e.g., an X direction) may be greater than a second width a2 (FIG. 3) that is a width of the bottom surface PHU of plurality of pad holes PH in the first horizontal direction (e.g., the X direction). For example, a minimum width of the plurality of pad holes PH in the first horizontal direction (e.g., the X direction) may be the second width a2 that is the width of the bottom surface PHU of the plurality of pad holes PH in the first horizontal direction (e.g., the X direction).

According to an embodiment, the plurality of pad holes PH may pass through the uppermost sub interposer insulation layer USI (e.g., the third interposer insulation layer 216). For example, the plurality of pad holes PH may be defined by an inner sidewall of the third interposer insulation layer 216 and an upper surface of the second sub interposer insulation layer 214. For example, the inner sidewall PHS of each of the plurality of pad holes PH may be the inner sidewall of the third interposer insulation layer 216, and the bottom surface PHU of each of plurality of pad holes PH may be the upper surface of the second sub interposer insulation layer 214.

According to an embodiment, the first to the third interposer redistribution structures 220 to 240 may be sequentially stacked on the second lower insulation layer 202 in the vertical direction (e.g., the Z direction). According to an embodiment, the first to the third interposer redistribution structures 220 to 240 may be at least partially surrounded by the second lower insulation layer 202 and the first to third sub interposer insulation layers 212, 214, and 216.

In FIG. 1, the interposer substrate 200 is illustrated as including three base redistribution structures. However, embodiments of the present disclosure are not necessarily limited thereto. For example, in some embodiments the interposer substrate 200 may include two interposer redistribution structures that are sequentially stacked, or may include four or more interposer redistribution structures that are sequentially stacked.

According to an embodiment, the first interposer redistribution structure 220 may be a lowermost interposer redistribution structure of the interposer substrate 200. According to an embodiment, the first interposer redistribution structure 220 may include a plurality of first conductive interposer seed layers 222, a plurality of first conductive interposer pads 224, and a plurality of first conductive interposer patterns 226.

According to an embodiment, the plurality of first conductive interposer patterns 226 may extend in the horizontal direction (e.g., the X direction and/or the Y direction) on the second lower insulation layer 202. According to an embodiment, the first sub interposer insulation layer 212 may surround the plurality of first conductive interposer patterns 226, on the second lower insulation layer 202. According to an embodiment, the plurality of first conductive interposer pads 224 may pass through the second lower insulation layer 202 in the vertical direction (e.g., the Z direction) on the plurality of conductive posts 172 and may respectively contact the plurality of first conductive interposer patterns 226. In some embodiments, each of the plurality of first conductive interposer patterns 226 and a corresponding first conductive interposer pad 224 connected thereto may be provided in an integrated structure.

According to an embodiment, each of the plurality of first conductive interposer seed layers 222 may include a portion disposed between the first conductive interposer pattern 226 and the second lower insulation layer 202, a portion between the plurality of first conductive interposer pads 224 and the second lower insulation layer 202, and a portion disposed between the plurality of first conductive interposer pads 224 and the plurality of conductive posts 172. For example, a lower surface of each of the plurality of first conductive interposer seed pads 224 may face an upper surface of the conductive post 172 with the first conductive interposer seed layer 222 therebetween.

In some embodiments, a lower surface of each of the plurality of first conductive interposer pads 224 may be disposed at the same level as a lower surface of the second lower insulation layer 202 in the vertical direction (e.g., the Z direction). However, embodiments of the present disclosure are not necessarily limited thereto. For example, in some embodiments, the lower surface of each of the plurality of first conductive interposer pads 224 may not be disposed at the same level as the lower surface of the second lower insulation layer 202 in the vertical direction (the Z direction). For example, in an embodiment the lower surface of each of the plurality of first conductive interposer pads 224 may be disposed at a level that is higher than the lower surface of the second lower insulation layer 202 in the vertical direction (e.g., the Z direction). For example, the lower surface of each of the plurality of first conductive interposer pads 224 may be disposed at a level that is lower than the lower surface of the second lower insulation layer 202 in the vertical direction (e.g., the Z direction).

According to an embodiment, the second interposer redistribution structure 230 may be disposed on the first interposer redistribution structure 220. According to an embodiment, the second interposer redistribution structure 230 may include a plurality of second conductive interposer seed layers 232, a plurality of second conductive interposer vias 234, and a plurality of second conductive interposer patterns 236. According to an embodiment, the plurality of second conductive interposer patterns 236 may extend in the horizontal direction (e.g., the X direction and/or the Y direction) on an upper surface of the first sub interposer insulation layer 212 and may be surrounded by the second sub interposer insulation layer 214. According to an embodiment, each of the plurality of second conductive interposer vias 234 may pass through the first sub interposer insulation layer 212 in the vertical direction (e.g., the Z direction) on the first conductive interposer pattern 226 and may connect the first conductive interposer pattern 226 with the second conductive interposer pattern 236. According to an embodiment, each of the plurality of second conductive interposer seed layers 232 may include a portion disposed between the second conductive interposer pattern 236 and the first sub interposer insulation layer 212, a portion between the plurality of second conductive interposer vias 234 and the first sub interposer insulation layer 212, and a portion disposed between the plurality of second conductive interposer vias 234 and the plurality of first conductive interposer patterns 226. According to an embodiment, each of the plurality of second conductive interposer patterns 236 and a corresponding second conductive interposer via 234 connected thereto may be provided in an integrated structure.

According to an embodiment, the third interposer redistribution structure 240 may be disposed on the second interposer redistribution structure 230. According to an embodiment, the third interposer redistribution structure 240 may correspond to an interposer redistribution structure disposed uppermost in the vertical direction (e.g., the Z direction) among the plurality of interposer redistribution structures 220 to 240. For example, the third interposer redistribution structure 240 may be an uppermost interposer redistribution structure (UIRD).

According to an embodiment, the third interposer redistribution structure 240 may include a plurality of third conductive interposer seed layers 242, a plurality of third conductive interposer vias 244, and a plurality of third conductive interposer patterns 246. For example, the plurality of third conductive interposer patterns 246 may respectively correspond to a plurality of uppermost conductive interposer patterns UIP.

Referring to FIGS. 4 and 5, the plurality of third conductive interposer patterns 246 may be disposed on an upper surface of the second sub interposer insulation layer 214. According to an embodiment, the plurality of third conductive interposer patterns 246 may include a plurality of conductive pad patterns 246a having a dot shape and a plurality of conductive line patterns 246b having a line shape extending in the horizontal direction (e.g., the X direction and/or the Y direction). For example, the plurality of conductive pad patterns 246a may have an independent island shape in a plane (e.g., in a plan view defined in the X and Y directions). According to an embodiment, a side surface 246S of each of the plurality of third conductive interposer patterns 246 may be vertical to the upper surface 210U of the interposer insulation layer 210. For example, the side surface of each of the plurality of third interposer patterns 246 may be orthogonal to an extending direction of an upper surface 210U of the interposer insulation layer 210. However, embodiments of the present disclosure are not necessarily limited thereto and the side surface of the plurality of third interposer patterns 246 may extend at other directions that cross the extending direction of the upper surface 210U of the interposer insulation layer.

According to an embodiment, each of the plurality of third conductive interposer vias 244 may pass through the second sub interposer insulation layer 214 in the vertical direction (e.g., the Z direction) on the second conductive interposer pattern 236 and may connect the second conductive interposer pattern 236 with the third conductive interposer pattern 246. According to an embodiment, each of the plurality of third conductive interposer seed layers 242 may include a portion disposed between the third conductive interposer pattern 246 and the second sub interposer insulation layer 214, a portion between the plurality of third conductive interposer vias 244 and the second sub interposer insulation layer 214, and a portion disposed between the plurality of third conductive interposer vias 244 and the plurality of second conductive interposer patterns 236. According to an embodiment, each of the plurality of third conductive interposer patterns 246 and a corresponding third conductive interposer via 244 connected thereto may be provided in an integrated structure.

According to an embodiment, the plurality of first to third conductive interposer seed layers 222, 232, and 242 may each include copper (Cu), titanium (Ti), titanium tungsten (TiW), titanium nitride (TiN), tantalum (Ta), tantalum nitride (TaN), chromium (Cr), aluminum (Al), or a combination thereof. However, embodiments of the present disclosure are not necessarily limited thereto. According to an embodiment, the plurality of first to third conductive interposer seed layers 222, 232, and 242 may each include Cu/Ti in which copper is stacked on titanium or Cu/TiW in which copper is stacked on titanium tungsten.

According to an embodiment, the plurality of first conductive interposer pads 224 may include metal, such as copper (Cu), aluminum (Al), tungsten (W), titanium (Ti), tantalum (Ta), indium (In), molybdenum (Mo), manganese (Mn), cobalt (Co), zinc (Sn), nickel (Ni), magnesium (Mg), rhenium (Re), beryllium (Be), gallium (Ga), or ruthenium (Ru), or an alloy thereof.

According to an embodiment, each of the plurality of second and third conductive interposer vias 234 and 344 and the plurality of first to third conductive interposer patterns 226, 236, and 246 may include metal, such as copper (Cu), aluminum (Al), tungsten (W), titanium (Ti), tantalum (Ta), indium (In), molybdenum (Mo), manganese (Mn), cobalt (Co), zinc (Sn), nickel (Ni), magnesium (Mg), rhenium (Re), beryllium (Be), gallium (Ga), or ruthenium (Ru), or an alloy thereof.

According to an embodiment, the plurality of third conductive interposer patterns 246 may be at least partially exposed through the plurality of pad holes PH, respectively. In an embodiment, the plurality of third conductive interposer patterns 246 may be respectively disposed on the bottom surfaces of the plurality of pad holes PH. Referring to FIGS. 4 and 5, in a plane, the conductive pad pattern 246a may be disposed in the pad hole PH, and the conductive line pattern 246b may cross the pad hole PH.

According to an embodiment, the plurality of third conductive interposer patterns 246 may have a third width b1 that is a width thereof in the first horizontal direction (e.g., the X direction). For example, the third width b1 may be a width of the conductive pad pattern 246a having a dot shape in the first horizontal direction (e.g., the X direction). For example, the conductive line pattern 246b may cross the pad hole PH in the second horizontal direction (e.g., the Y direction) in a plane, and in this embodiment, the third width b1 may be a width of the conductive line pattern 246b in the first horizontal direction (e.g., the X direction).

According to an embodiment, the second width a2 that is a width of the plurality of pad holes PH in the first horizontal direction (e.g., the X direction) may be greater than or equal to the third width b1 that is a width of the plurality of third conductive interposer patterns 246 in the first horizontal direction (e.g., the X direction). In embodiments shown in FIGS. 1 and 3, it is illustrated that the second width a2 of the plurality of pad holes PH is greater than the third width b1 of the plurality of third conductive interposer patterns 246 (e.g., the plurality of uppermost conductive interposer patterns). However, embodiments of the present disclosure are not necessarily limited thereto. For example, in an embodiment the second width a2 of the plurality of pad holes PH may be equal to the third width b1 of the plurality of third conductive interposer patterns 246.

According to an embodiment, the side surface 246S of each third interposer pattern 246 may include a portion apart from the inner sidewall PHS of each pad hole PH. For example, a side surface of each conductive pad pattern 246a may be apart from the inner sidewall PHS of each pad hole PH. For example, a side surface of each conductive line pattern 246b in the first horizontal direction (the X direction) may include a portion apart from the inner sidewall PHS of each pad hole PH.

According to an embodiment, the side surface 246S of the plurality of third interposer patterns 246 may be exposed through the plurality of pad holes PH and may not be covered by the interposer insulation layer 210. For example, the side surface 246S of the plurality of third interposer patterns 246 may not contact the third sub interposer insulation layer 216. The third sub interposer insulation layer 216 may be spaced apart from the side surface 246S of the plurality of third interposer patterns 246 (e.g., in the X and/or Y directions). According to an embodiment, each of the plurality of third conductive interposer seed layers 242 may include a portion exposed by a corresponding pad hole PH of the plurality of pad holes PH.

According to an embodiment, in the plurality of pad holes PH, a plurality of conductive connection pads 252 may be disposed on the plurality of third interposer patterns 246. According to an embodiment, the plurality of conductive connection pads 252 may have a dot shape and may respectively overlap the plurality of third interposer patterns 246 in the vertical direction (e.g., the Z direction). For example, in a plane, the plurality of conductive connection pads 252 may have an independent island shape. According to an embodiment, a fourth width b2 that is a width of the plurality of conductive connection pads 252 in the first horizontal direction (e.g., the X direction) may be less than the third width b1 that is a width of the plurality of third conductive interposer patterns 246 in the first horizontal direction (e.g., the X direction).

In an embodiment, the semiconductor package 1a may not include a separate conductive via structure that connects each conductive connection pad 252 with a corresponding third conductive interposer pattern 246, between each conductive connection pad 252 and the corresponding third conductive interposer pattern 246. For example, each conductive connection pad 252 may contact a corresponding third conductive interposer pattern 246 directly or with a conductive pad seed layer 254, which is described below, therebetween, and thus, the electrical reliability of the semiconductor package 1a may be increased.

According to an embodiment, an upper surface 252U of each of the plurality of third conductive connection pads 252 may be disposed at a level (e.g., a height from the base substrate 100 in the vertical direction) that is lower than the upper surface 210U of the interposer insulation layer 210 in the vertical direction (e.g., the Z direction). According to an embodiment, the upper surface 252U of each of the plurality of third conductive connection pads 252 may be disposed at a level that is a first length cl lower than the upper surface 210U of the interposer insulation layer 210 in the vertical direction (e.g., the Z direction). According to an embodiment, the first length cl may be in a range of about 0.1 μm to about 5 μm. However, embodiments of the present disclosure are not necessarily limited thereto. For example, in some embodiments the height of the upper surface 252U of each of the plurality of third connection pads 252 may be equal to a height of the upper surface 210U of the interposer insulation layer 210 in the vertical direction (e.g., the Z direction).

According to an embodiment, each of the plurality of third conductive connection pads 252 may be spaced apart from the inner sidewall PHS of a corresponding pad hole PH (e.g., in the X and/or Y directions). According to an embodiment, the upper surface 252U and the side surface of the third conductive connection pad 252 may not be covered by the interposer insulation layer 210. For example, the upper surface 252U and the side surface of the third conductive connection pad 252 may be exposed through the pad hole PH. According to an embodiment, the side surface of each of the plurality of third conductive connection pads 252 may be vertical to the upper surface 210U of the interposer insulation layer 210. For example, the side surface of each of the plurality of third conductive connection pads 252 may be orthogonal to an extending direction of an upper surface 210U of the interposer insulation layer 210. However, embodiments of the present disclosure are not necessarily limited thereto and the side surface of the plurality of third conductive connection pads 252 may extend at other directions that cross the extending direction of the upper surface 210U of the interposer insulation layer 210.

According to an embodiment, the upper surfaces 246U of the plurality of third conductive interposer patterns 246 may be partially exposed through the plurality of pad holes PH, respectively. For example, a portion of the upper surfaces 246U of the plurality of third conductive interposer patterns 246 that does not vertically overlap each conductive connection pad 252, of the upper surface 246U of each third interposer pattern 246 may not be covered by the interposer insulation layer 210 and may be exposed through the pad hole PH.

In an embodiment, the interposer insulation layer 210 of the semiconductor package 1a may not cover side surfaces of the plurality of uppermost conductive interposer patterns UIP and the plurality of conductive connection pads 252, that are exposed through the plurality of pad holes PH. Accordingly, the occurrence of a crack of the interposer insulation layer 210 caused by the expansion or contraction of the plurality of uppermost conductive interposer patterns UIP and the plurality of conductive connection pads 252 may be prevented, and thus, the structural and electrical reliability of the semiconductor package 1a may be increased.

According to an embodiment, the semiconductor package 1a may further include a conductive pad seed layer 254 that is disposed between the plurality of conductive connection pads 252 and the plurality of third conductive interposer patterns 246 and covers a lower surface of each of the plurality of conductive connection pads 252. For example, a plurality of conductive pad seed layers 254 may respectively overlap the plurality of conductive connection pads 252 in the vertical direction (e.g., the Z direction). For example, a width of the plurality of conductive pad seed layers 254 in the first horizontal direction (e.g., the X direction) may be equal to a fourth width b2 which is a width of the plurality of conductive pad seed layers 254 in the first horizontal direction.

According to an embodiment, the plurality of conductive connection pads 252 may include copper (Cu), nickel (Ni), aluminum (Al), silver (Ag), gold (Au), chromium (Cr), titanium (Ti), palladium (Pd), or an alloy thereof. According to an embodiment, the plurality of conductive connection pads 252 may include Ni/Au where Au is stacked on Ni. However, embodiments of the present disclosure are not necessarily limited thereto.

According to an embodiment, the plurality of pad seed layers may include metal, such as copper (Cu), titanium (Ti), titanium tungsten (TiW), titanium nitride (TiN), tantalum (Ta), tantalum nitride (TaN), chromium (Cr), aluminum (Al), or nickel (Ni), or an alloy thereof. However, embodiments of the present disclosure are not necessarily limited thereto.

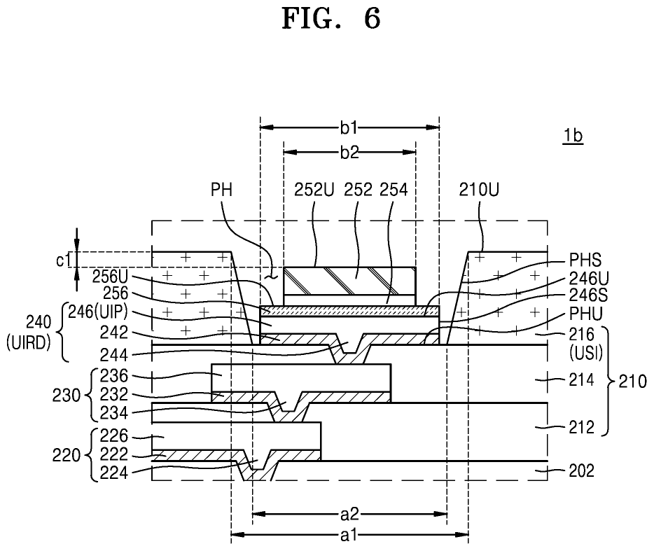

FIG. 6 is an enlarged view of a region corresponding to the region EX2 of FIG. 1, in a semiconductor package 1b according to some embodiments. The difference between FIG. 6 and FIG. 3 may denote whether the semiconductor package 1b further includes a conductive barrier layer 256.

Referring to FIG. 6, the semiconductor package 1b may include a plurality of conductive barrier layers 256 that are each disposed between a corresponding conductive connection pad 252 of a plurality of conductive connection pads 252 and a third conductive interposer pattern 246 of a plurality of third conductive interposer patterns 246 and each cover an upper surface 246U of a corresponding third conductive interposer pattern 246 of a plurality of third conductive interposer patterns 246. For example, a width of the plurality of conductive barrier layers 256 in a first horizontal direction (e.g., an X direction) may be equal to a third width b1 that is a width of the plurality of third conductive interposer patterns 246 in the first horizontal direction (e.g., the X direction). Thus, the edges of the plurality of conductive barrier layers 256 and the plurality of third conductive interposer patterns 246 may be aligned with each other. According to an embodiment, each of the plurality of conductive barrier layers 256 may face the conductive connection pad 252 with the conductive pad seed layer 254 therebetween (e.g., in the Z direction). According to an embodiment, each of the plurality of conductive barrier layers 256 may overlap the third conductive interposer pattern 246 in a vertical direction (e.g., a Z direction), and upper surfaces 256U of the plurality of conductive barrier layers 256 may be partially exposed through a plurality of pad holes PH, respectively. In this embodiment, the upper surfaces 246U of the plurality of third conductive interposer patterns 246 may be covered by the plurality of conductive barrier layers 256 and may not be exposed. According to an embodiment, the third conductive interposer pattern 246 may be prevented from being deformed or damaged from external pollution or stress.

According to an embodiment, the plurality of conductive barrier layers 256 may include metal that is high in corrosion resistance. According to an embodiment, the plurality of conductive barrier layers 256 may include Cr, Al, Ti, or Ni. However, embodiments of the present disclosure are not necessarily limited thereto.

According to an embodiment, a first thickness that is a thickness of the plurality of conductive barrier layers 256 in the vertical direction (e.g., the Z direction) may be less than a second thickness that is a thickness of the plurality of third conductive interposer patterns 246 in the vertical direction (e.g., the Z direction). According to an embodiment, a ratio of the second thickness of the plurality of third conductive interposer patterns 246 to the first thickness of the plurality of conductive barrier layers 256 may be about 1:6, and for example, may be about 1:3. However, embodiments of the present disclosure are not necessarily limited thereto. According to an embodiment of the present disclosure as described above, the electrical reliability of the semiconductor package 1b may be secured.

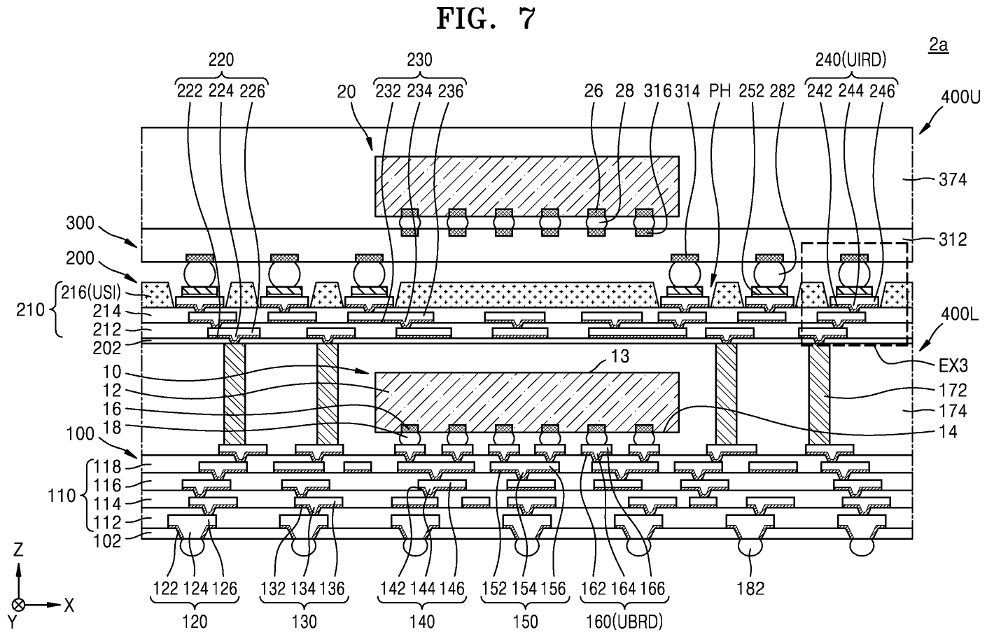

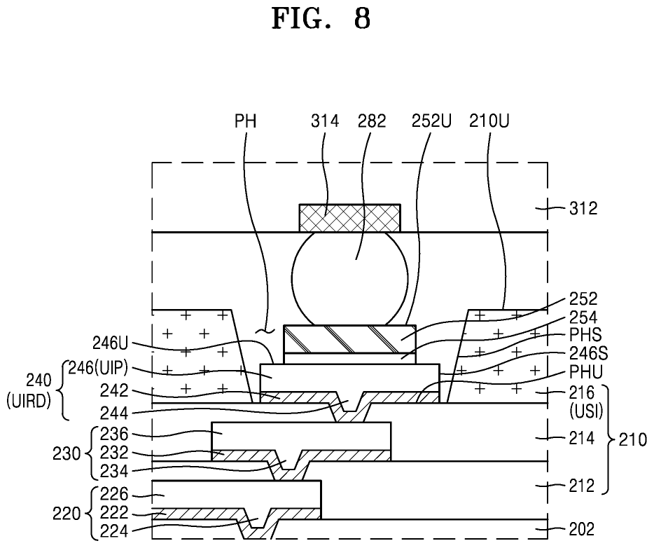

FIG. 7 is a cross-sectional view illustrating a package-on-package type semiconductor package in which an upper package 400U is stacked on a lower package 400L, in a semiconductor package 2a according to an embodiment. FIG. 8 is an enlarged view of a region EX3 of FIG. 7.

In FIG. 7, it is illustrated that the lower package 400L including the interposer substrate 200 corresponds to the semiconductor package 1a described above with reference to FIGS. 1 to 5. However, embodiments of the present disclosure are not necessarily limited thereto and the lower package 400L may correspond to the semiconductor package 1b described above with reference to FIG. 6. In the semiconductor packages 1a and 1b described above with reference to FIGS. 1 to 6, the base substrate 100 may be referred to as a first base substrate, the semiconductor chip 10 may be referred to as a first semiconductor chip, the chip pad 16 may be referred to as a first chip pad, the chip connection member 18 may be referred to as a first chip connection terminal, the molding layer 174 may be referred to as a first molding layer, and the external connection terminal 182 may be referred to as a first external connection terminal.

Referring to FIGS. 7 and 8, the upper package 400L may include a second base substrate 300, a second semiconductor chip 20, and a second molding layer 374. According to an embodiment, the second base substrate 300 may be, for example, a printed circuit board (PCB). However, embodiments of the present disclosure are not necessarily limited thereto. In an embodiment, the second base substrate 300 may include a second base insulation layer 312 including at least one material selected from among phenol resin, epoxy resin, and polyimide. Also, the second base substrate 300 may include a plurality of lower substrate pads 314 disposed on a lower surface of the second base insulation layer 312 and a plurality of upper substrate pads 316 disposed on an upper surface of the second base insulation layer 312. An internal wiring configured to electrically connect the plurality of lower substrate pads 314 with the plurality of upper substrate pads 316 may be formed in the second base insulation layer 312.

According to an embodiment, the semiconductor package 2a may include a plurality of second external connection terminals 282 that are each disposed between the lower substrate pad 314 and a conductive connection pad 252 and are each configured to electrically connect the second base substrate 300 with an interposer substrate 200. According to an embodiment, the plurality of second external connection terminals 282 may be respectively attached on upper surfaces 252U of a plurality of conductive connection pads 252. For example, the plurality of second external connection terminals 282 may not cover upper surfaces 246U and side surfaces 246S of a plurality of third conductive interposer patterns 246. According to an embodiment, each of the side surfaces 246S of the plurality of third conductive interposer patterns 246 may include a portion spaced apart from an inner sidewall PHS of a corresponding pad hole PH of a plurality of pad holes PH. For example, each of the plurality of second external connection terminals 282 may be a solder ball or a bump. However, embodiments of the present disclosure are not necessarily limited thereto.

According to an embodiment, the second semiconductor chip 20 may be attached on the second base substrate 300. For example, a plurality of second chip pads 26 of the second semiconductor chip 20 may be electrically connected with an upper substrate pad 316 of the second base substrate 300 through a plurality of second chip connection members 28.

According to an embodiment, a second molding layer 374 which at least partially surrounds the second semiconductor chip 20 and the plurality of second chip connection members 28 may be disposed on the second base substrate 300. According to an embodiment, the second molding layer 374 may include epoxy-based mold resin or polyimide-based mold resin. For example, the uppermost conductive base pattern may be a molding member including an EMC.

According to an embodiment, the first semiconductor chip 10 and the second semiconductor chip 20 may each be a homogeneous semiconductor chip. However, embodiments of the present disclosure are not necessarily limited thereto. For example, in an embodiment the first semiconductor chip 10 and the second semiconductor chip 20 may be heterogeneous semiconductor chips. For example, in an embodiment in which the first semiconductor chip 10 is a logic chip, the second semiconductor chip 20 may be a memory chip. According to an embodiment, the second semiconductor chip 20 may be a high bandwidth memory (HBM) memory chip. In some embodiments, the upper package 400L may include a plurality of second semiconductor chips 20. According to an embodiment, the semiconductor package 2a may be configured so that parts such as different kinds of semiconductor chips and passive devices are electrically connected with one another and operate as one system.

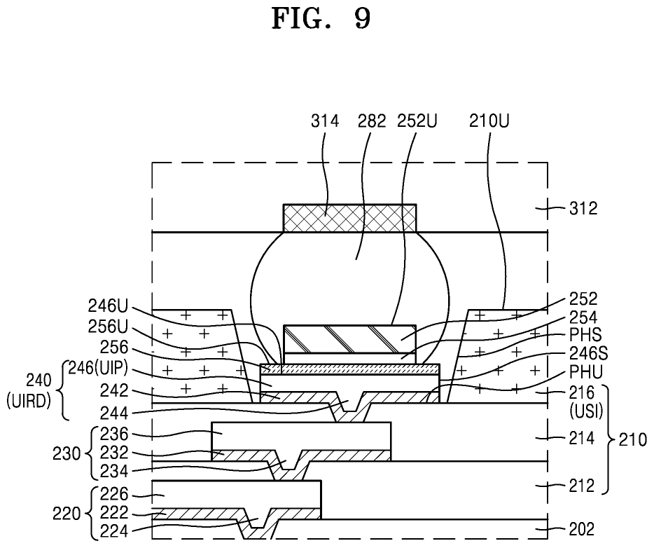

FIG. 9 is an enlarged view of the region EX3 of FIG. 7, in a package-on-package type semiconductor package 2b according to some embodiments. The difference between FIG. 9 and FIG. 8 may denote whether the semiconductor package 2b further includes a conductive barrier layer 256. Descriptions which are the same as or similar to the descriptions of FIG. 6 may be omitted for economy of description.

Referring to FIG. 9, the semiconductor package 2b may include a plurality of conductive barrier layers 256 that respectively cover upper surfaces 246U of a plurality of third conductive interposer patterns 246. According to an embodiment, a plurality of second external connection terminals 282 may respectively cover a plurality of conductive connection pads 252. In this embodiment, the plurality of second external connection terminals 282 may respectively contact upper surfaces 256U of the plurality of conductive barrier layers 256, and each of the plurality of third conductive interposer patterns 246 may be spaced apart from the second external connection terminal 282 with the conductive barrier layer 256 therebetween. Accordingly, the pollution or damage of the third conductive interposer pattern 246 caused by the second external connection terminal 282 may be prevented, and thus, the structural stability and electrical reliability of the semiconductor package 2b may be increased.

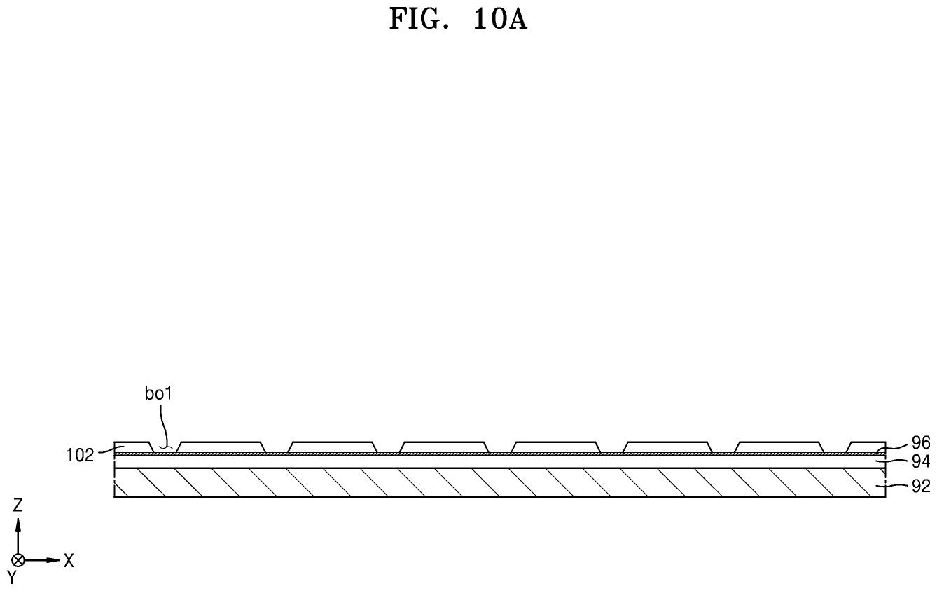

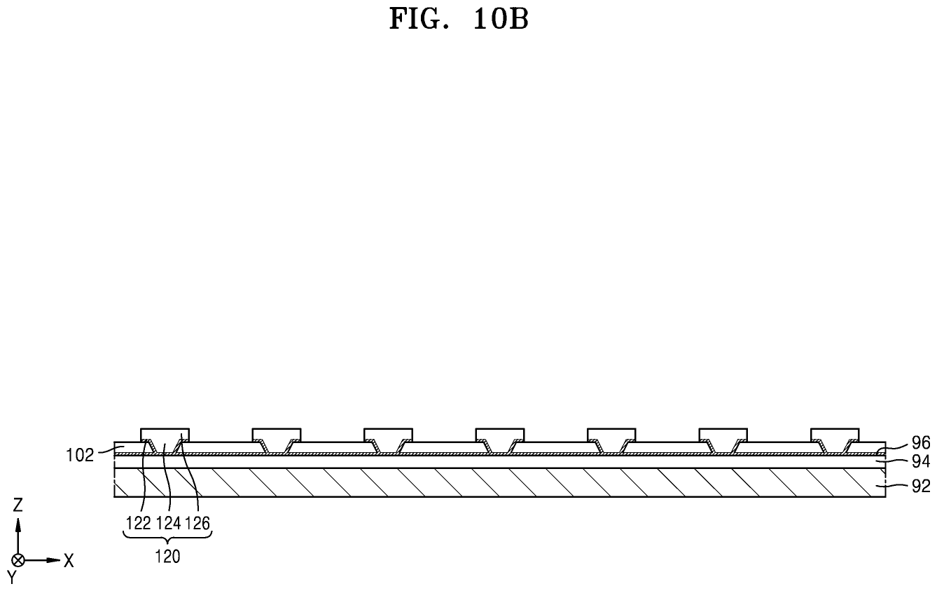

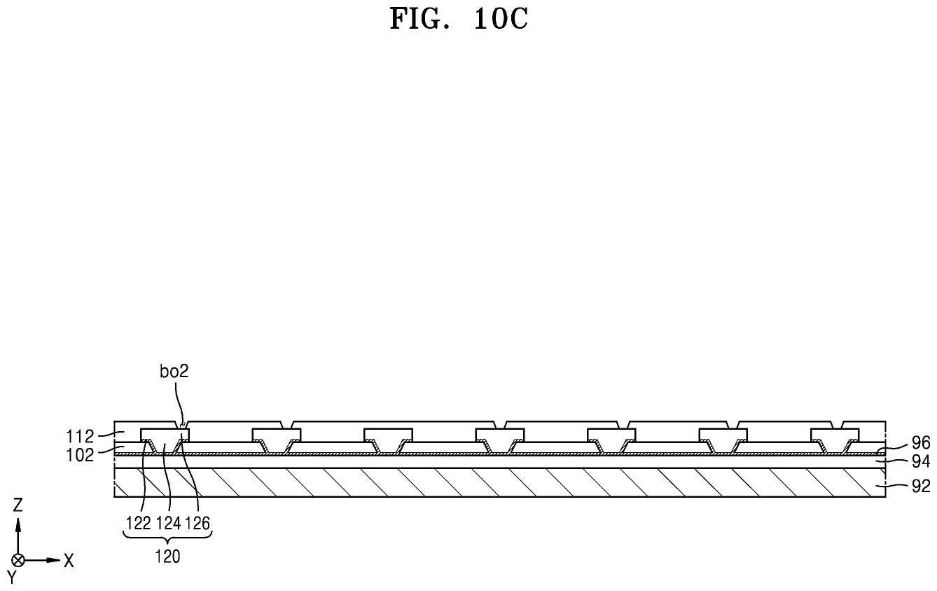

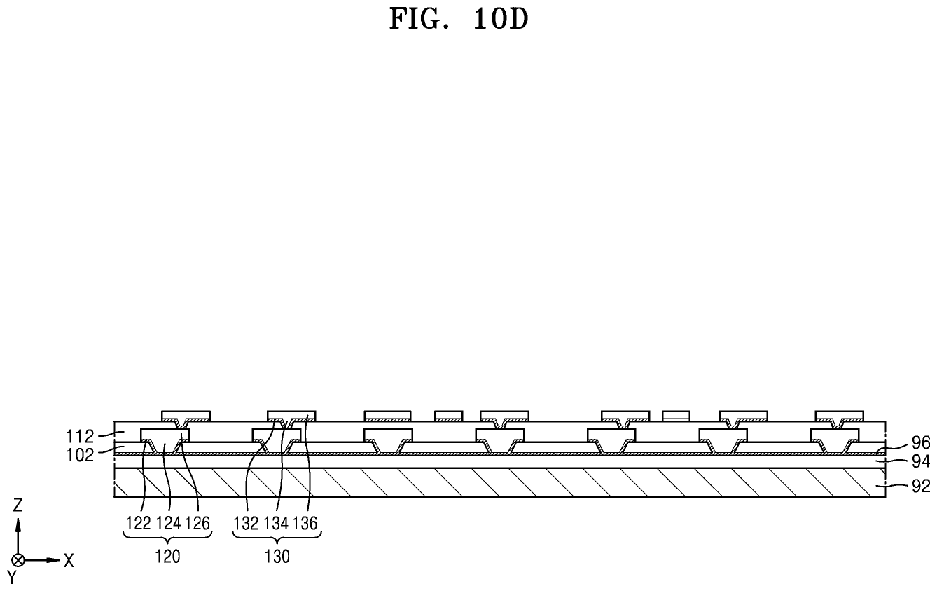

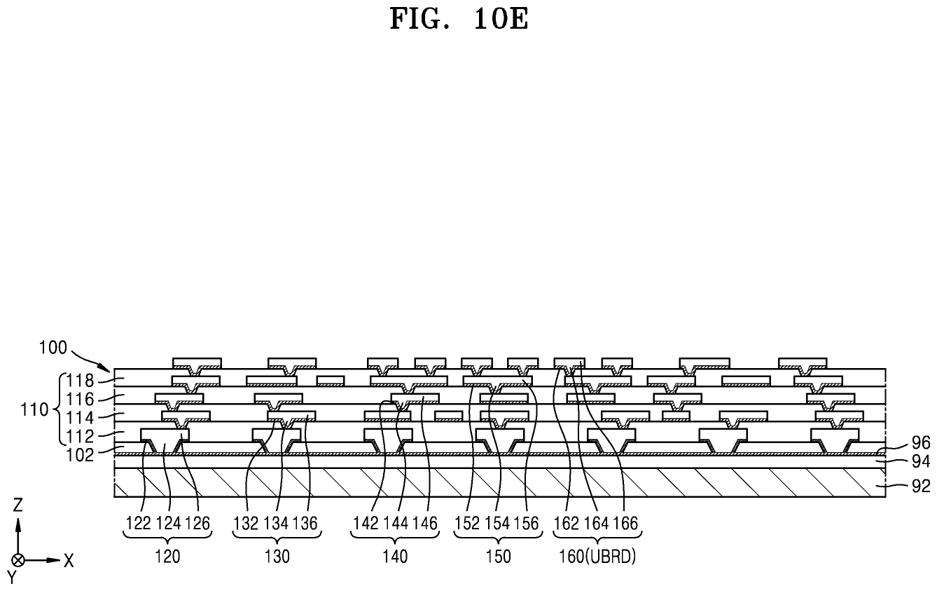

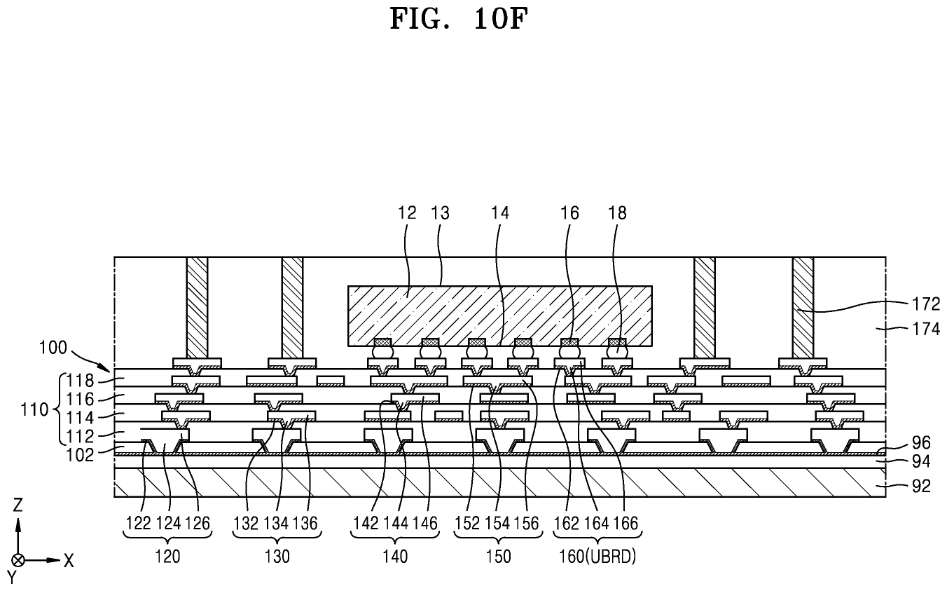

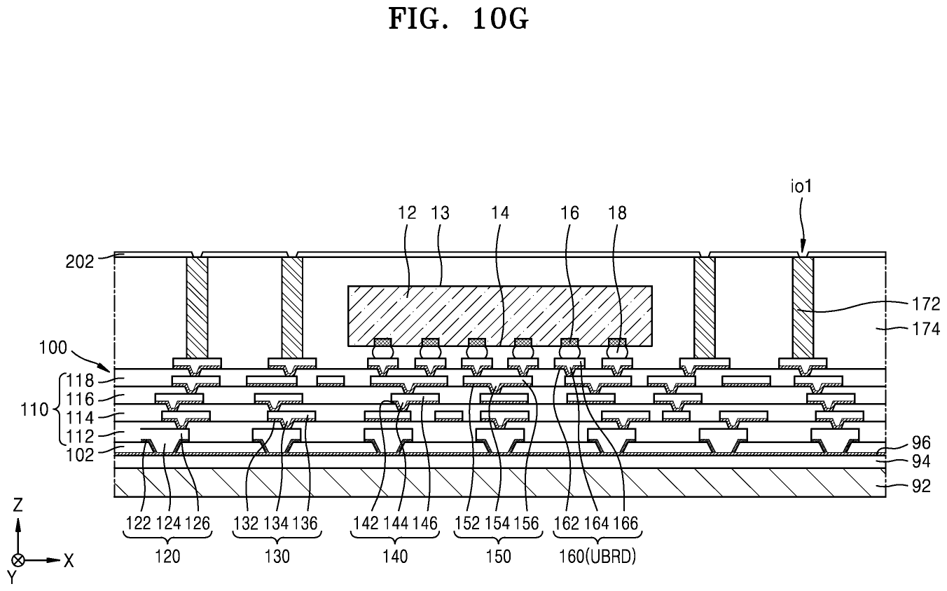

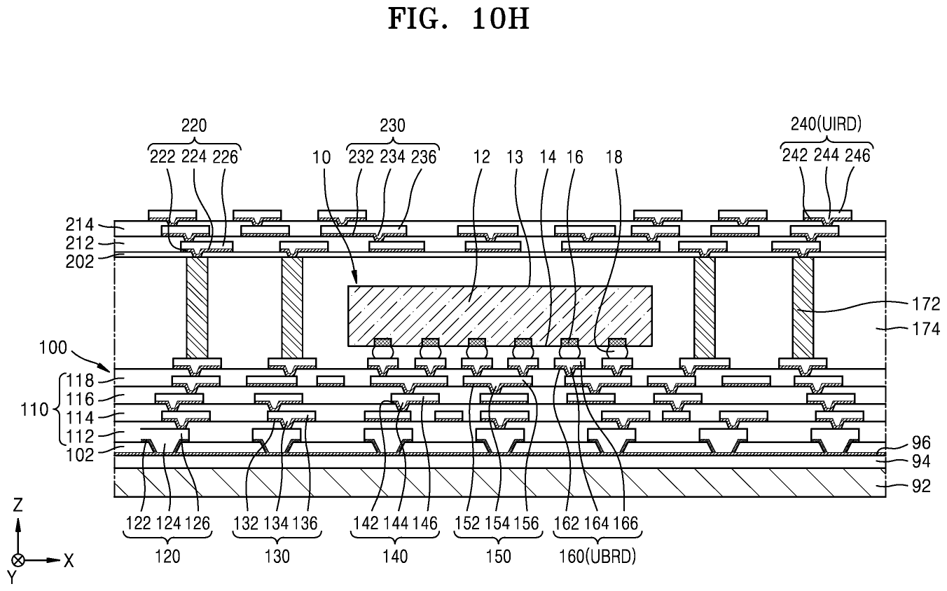

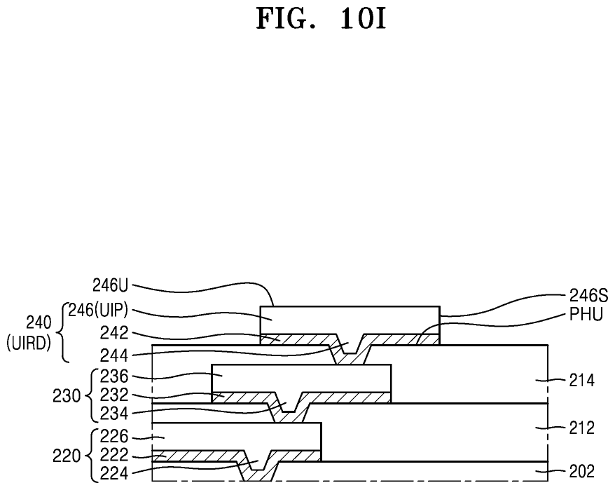

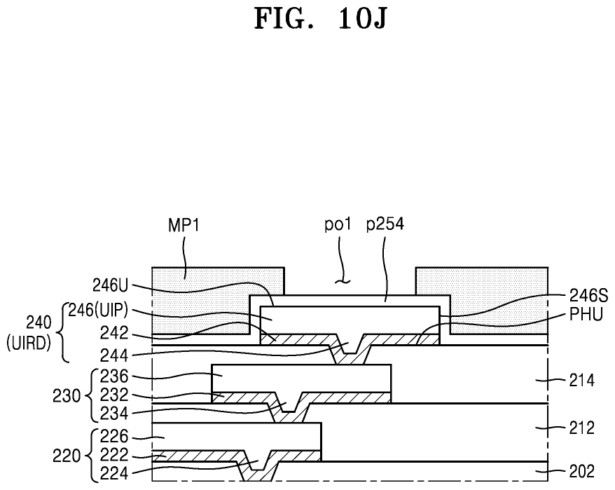

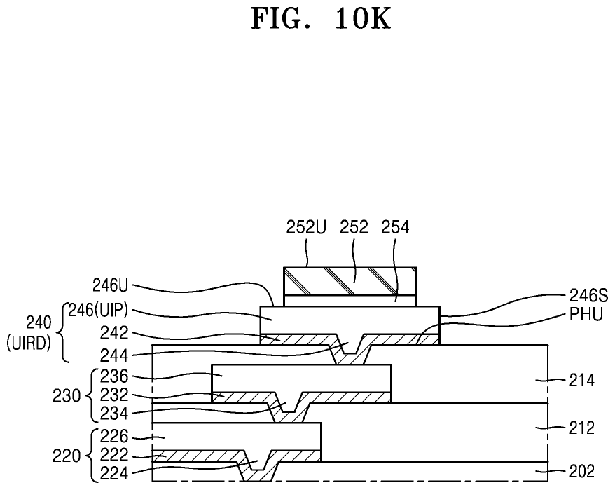

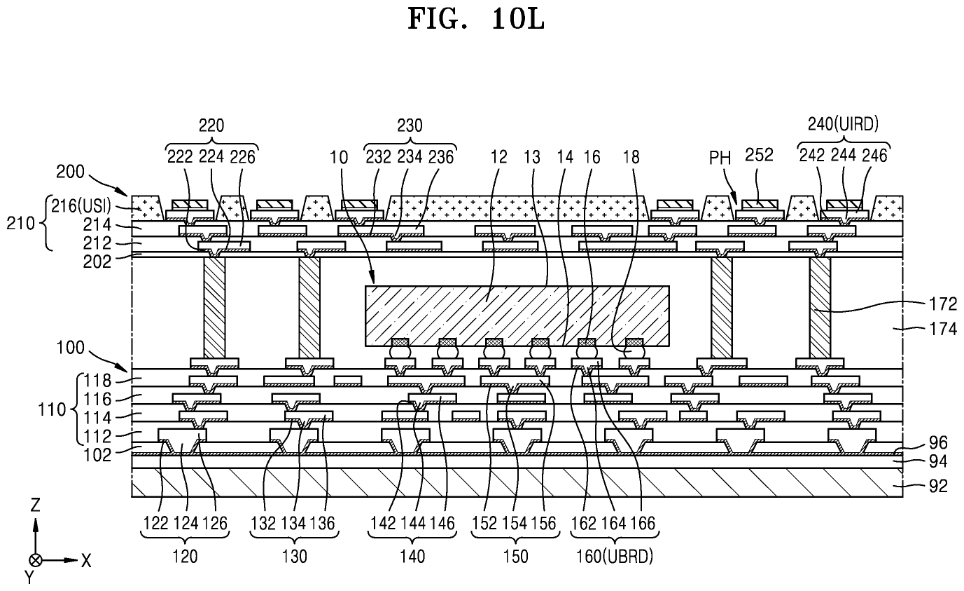

FIGS. 10A to 10L are cross-sectional views illustrating a method of manufacturing a semiconductor package in sequence, according to embodiments, and FIGS. 10I to 10L are enlarged cross-sectional views of a region EX2 of FIG. 1. Hereinafter, a method of manufacturing the semiconductor package 1a described above with reference to FIGS. 1 to 5 is described with reference to FIGS. 10A to 10L.

Referring to FIG. 10A, a release layer 94, an etch stop layer 96, and a first lower insulation layer 102 may be sequentially formed on a carrier substrate 92. According to an embodiment, the carrier substrate 92 may be a glass substrate. However, embodiments of the present disclosure are not necessarily limited thereto. For example, in some embodiments the carrier substrate 92 may include a heat-resistance organic polymer material, such as polyimide (PI), poly(etheretherketone) (PEEK), poly(ethersulfone) (PES), or poly(phenylene sulfide) (PPS). According to an embodiment, the carrier substrate 92 may include an amorphous carbon layer (ACL) or a spin-on hard mask (SOH) which is a layer including a hydrocarbon compound having a relatively high carbon content in a range of about 85 wt % to about 99 wt/o with respect to the total wt % thereof, or derivatives thereof. However, embodiments of the present disclosure are not necessarily limited thereto. For example, the release layer 94 may include a PID. According to an embodiment, the etch stop layer 96 may include a material having etch selectivity with respect to the first lower insulation layer 102. For example, the etch stop layer 96 may include metal, such as Ti.

According to an embodiment, a first base opening bo1 passing through the first lower insulation layer 102 and exposing the etch stop layer 96 may be formed. For example, in an embodiment the first base opening bo1 may be formed by a photoresist process. According to an embodiment, the first base opening bo1 may have a shape in which a width of a horizontal cross-sectional surface narrows toward a lower surface of the first lower insulation layer 102 from an upper surface thereof.

Referring to FIG. 10B, in a resultant product of FIG. 10A, a conductive material layer conformally covering the upper surface of the first lower insulation layer 102 and an inner surface and a bottom surface of the first base opening bo1 may be formed. In an embodiment, a mask pattern exposing the first base opening bo1 may then be provided and a first conductive base pad 124 and a first conductive base pattern 126 may be formed by a plating process in an exposed region. Subsequently, after the mask pattern is removed, a first conductive base seed layer 122 may be formed by removing a portion of the conductive material layer, and thus, a first base redistribution structure 120 may be formed.

Referring to FIGS. 10C and 10D, in a resultant product of FIG. 10B, a first sub base insulation layer 112 covering the first base redistribution structure 120 may be formed on the first lower insulation layer 102. In an embodiment, a second base opening bo2 passing through the first sub base insulation layer 112 and exposing the first conductive base pattern 126 may then be formed by a photoresist process.

Subsequently, a conductive material layer conformally covering an upper surface of the first sub base insulation layer 112 and an inner surface and a bottom surface of the second base opening bo2 may be formed. According to an embodiment, a mask pattern exposing the second base opening bo2 may be provided, and a second conductive base via 134 and a second conductive base pattern 136 may be formed in an exposed region by a plating process using the conductive material layer. Subsequently, after the mask pattern is removed, a second conductive base seed layer 122 may be formed by removing a portion of a second conductive base seed layer 132, and thus, a second base redistribution structure 130 contacting the first base redistribution structure 120 may be formed.

Referring to FIG. 10E, in a resultant product of FIG. 10D, second to fourth sub base insulation layers 114, 116, and 118 and third to fifth base redistribution structures 140, 150, and 160 may be formed through substantially the same process as the descriptions of FIGS. 10C and 10D. For example, a second sub base insulation layer 114 covering the second base redistribution structure 130 may be formed, and then, a third base redistribution structure 140 contacting (e.g., directly contacting) the second base redistribution structure 130 may be formed on the second sub base insulation layer 114. Subsequently, a third sub base insulation layer 116 covering the third base redistribution structure 140 may be formed, and then, a fourth base redistribution structure 150 contacting (e.g., directly contacting) the third base redistribution structure 140 may be formed on the third sub base insulation layer 116. Subsequently, a fourth sub base insulation layer 118 covering the fourth base redistribution structure 150 may be formed, and then, a fifth base redistribution structure 160 contacting (e.g., directly contacting) the fourth base redistribution structure 150 may be formed on the fourth sub base insulation layer 118.

Referring to FIG. 10F, in a resultant product of FIG. 10E, a plurality of conductive posts 172 contacting some of a plurality of fifth conductive base patterns 166 of the fifth base redistribution structure 160 may be formed. For example, in an embodiment the plurality of conductive posts 172 may be formed by using a mask using a photoresist process. Subsequently, a semiconductor chip 10 may be attached on the base substrate 100. For example, in an embodiment a plurality of chip pads 16 may be connected with some of the plurality of fifth conductive base patterns 166 through a plurality of chip connection members 18. Subsequently, in the semiconductor chip 10, an under-fill layer surrounding the plurality of chip connection members 18 and some of the plurality of fifth conductive base patterns 166 connected with the plurality of chip connection members 18 may be formed. Subsequently, a molding layer 174 covering an upper surface of the base substrate 100 and surrounding the plurality of conductive posts 172, the semiconductor chip 10, and the plurality of fifth conductive base patterns 166 may be formed, and a planarization process may be performed thereon.

Referring to FIG. 10G, in an embodiment a second lower insulation layer 202 may be formed on a resultant product of FIG. 10F, and then, a mask pattern may be provided on the second lower insulation layer 202 and a first interposer opening io1 exposing an upper surface of each of the plurality of conductive posts 172 may be formed.

Referring to FIG. 10H, first and second sub interposer insulation layers 212 and 214 and first to third interposer redistribution structures 220, 230, and 240 may be formed on a resultant product of FIG. 10G through substantially the same process as the descriptions of FIGS. 10B to 10D. For example, in a resultant product of FIG. 10G, a conductive material layer conformally covering an upper surface of the second lower insulation layer 202 and an inner sidewall and a bottom surface of the first interposer opening io1 may be formed.

Subsequently, a mask pattern exposing the first interposer opening io1 may be formed, and then, a plurality of first conductive interposer pads 224 and a plurality of first conductive interposer patterns 226 may be formed on an exposed conductive material layer by performing a plating process. Subsequently, after the mask pattern is removed, a plurality of first conductive interposer seed layers 222 may be formed by removing a portion of the conductive material layer, and thus, a first interposer redistribution structure 220 may be formed.

Subsequently, a first sub interposer insulation layer 212 covering the first interposer redistribution structure 220 may be formed, and then, a second interposer redistribution structure 230 contacting (e.g., directly contacting) the first interposer redistribution structure 220 may be formed on the first sub interposer insulation layer 212. Subsequently, a second sub interposer insulation layer 214 covering the second interposer redistribution structure 230 may be formed, and then, a third interposer redistribution structure 240 contacting (e.g., directly contacting) the second interposer redistribution structure 230 may be formed on the second sub interposer insulation layer 214.

FIGS. 10I to 10K are enlarged cross-sectional views of a region corresponding to the region EX2 of FIG. 1, for describing a method of manufacturing the semiconductor package 1a after FIG. 10H.

Referring to FIGS. 10H, 10I, and 10J, in a resultant product of FIGS. 10H and 10I, a preliminary pad seed layer p254 conformally covering an upper surface of the second sub interposer insulation layer 214, an upper surface 246U and a side surface 246S of the third interposer redistribution pattern 246, and a portion of the third conductive interposer seed layer 242 may be formed. Subsequently, a first photo mask pattern MP1 may be formed on the preliminary pad seed layer p254, and thus, a plurality of first pad openings pol partially exposing the preliminary pad seed layer p254 on the plurality of third interposer redistribution patterns 246 may be formed.

Referring to FIG. 10K, in a resultant product of FIG. 10J, a plurality of conductive connection pads 252 filling the plurality of first pad openings pol may be formed by a plating process. Subsequently, after the first photo mask pattern MP1 is removed, a plurality of conductive pad seed layers 254 may be formed by removing a portion of the preliminary pad seed layer p254 through an etching process. In this embodiment, the upper surface 246U and the side surface 246S of each of the plurality of third interposer redistribution patterns 246 may be exposed.

Referring to FIGS. 10K and 10L, in a resultant product of FIG. 10K, in an embodiment an insulation layer covering the plurality of third interposer redistribution patterns 246 and the plurality of conductive connection pads 252 may be formed on the second sub interposer insulation layer 214. For example, an upper surface of the insulation layer may be disposed at a level that is higher than an upper surface 252U of each of the plurality of conductive connection pads 252, in a vertical direction (e.g., a Z direction). Subsequently, a plurality of pad holes PH exposing the plurality of conductive connection pads 252 may be formed by a photoresist process. In this embodiment, in the plurality of pad holes PH, an upper surface and a side surface of each of the plurality of third interposer redistribution patterns 246 may be exposed.

Referring to FIGS. 10L and 1, in a resultant product of FIG. 10L, the carrier substrate 92 may be detached from a lower surface of the release layer 94. For example, a laser beam may be irradiated onto the release layer 94, or heat may be applied to the release layer 94 to detach the carrier substrate 92. In some embodiments, a photo process may be performed. According to an embodiment, the carrier substrate 92 and the release layer 94 may be removed, and then, by removing the etch stop layer 96, lower surfaces of the plurality of first conductive base pads 124 may be exposed. For example, in a process of removing the etch stop layer 96, a portion of each of the plurality of first conductive base seed layers 122 formed between the etch stop layer 96 and the plurality of first conductive base pads 124 may be removed. Subsequently, a plurality of external connection terminals 182 (FIG. 1) may be attached on the lower surfaces of the plurality of first conductive base pads 124 that are exposed.

Embodiments of the present disclosure have been described by using the terms described herein, but this has been merely used for describing embodiments of the present disclosure and has not been used for limiting a meaning or limiting the scope of the present disclosure. Therefore, it may be understood by those of ordinary skill in the art that various modifications and other equivalent embodiments may be implemented from the present disclosure.

While the present disclosure have been particularly shown and described with reference to non-limiting embodiments thereof, it will be understood that various changes in form and details may be made therein without departing from the spirit and scope of the present disclosure.

What is claimed is:

1. A semiconductor package comprising:
a base substrate;
an interposer substrate including a plurality of interposer redistribution structures sequentially stacked in a vertical direction and an interposer insulation layer, the plurality of interposer redistribution structures including a plurality of conductive interposer patterns and a plurality of conductive interposer vias;
a semiconductor chip disposed between the base substrate and the interposer substrate in the vertical direction and attached on the base substrate; and
a plurality of conductive connection pads respectively disposed on a plurality of uppermost conductive interposer patterns of an uppermost interposer redistribution structure of the plurality of interposer redistribution structures,
wherein the interposer insulation layer comprises a plurality of pad holes, each pad hole of the plurality of pad holes exposing at least a portion of each of an upper surface of a corresponding conductive connection pad of the plurality of conductive connection pads and an upper surface of a corresponding uppermost conductive interposer pattern of the plurality of uppermost conductive interposer patterns, and
a side surface of each of the plurality of conductive connection pads is vertical to an upper surface of the interposer insulation layer, a side surface of each of the plurality of uppermost conductive interposer patterns is vertical to the upper surface of the interposer insulation layer, and an inner sidewall of each of the plurality of pad holes is inclined with respect to the upper surface of the interposer insulation layer.

2. The semiconductor package of claim 1, wherein the inner sidewalls of the plurality of pad holes are respectively spaced apart from the side surfaces of the plurality of uppermost conductive interposer patterns.

3. The semiconductor package of claim 1, wherein a width of the plurality of conductive connection pads in a first horizontal direction is less than a width of the plurality of uppermost conductive interposer patterns in the first horizontal direction.

4. The semiconductor package of claim 1, wherein a width of the plurality of pad holes in a first horizontal direction is greater than a width of the plurality of uppermost conductive interposer patterns in the first horizontal direction.

5. The semiconductor package of claim 1, wherein an uppermost surface of the interposer insulation layer is disposed at a height from an upper surface of the base substrate in the vertical direction that is greater than or equal to a height of the upper surfaces of the plurality of conductive connection pads from the upper surface of the base substrate in the vertical direction.

6. The semiconductor package of claim 1, wherein the plurality of uppermost conductive interposer patterns comprise a conductive line pattern extending in a horizontal direction and a conductive pad pattern having an independent island shape, in a plan view.

7. The semiconductor package of claim 1, further comprising a plurality of conductive pad seed layers disposed between the plurality of uppermost conductive interposer patterns and the plurality of conductive connection pads, the plurality of conductive pad seed layers respectively covering lower surfaces of the plurality of conductive connection pads.

8. The semiconductor package of claim 1, further comprising a plurality of conductive barrier layers disposed between the plurality of uppermost conductive interposer patterns and the plurality of conductive connection pads, the plurality of conductive barrier layers respectively covering the upper surfaces of the plurality of uppermost conductive interposer patterns and respectively exposed through the plurality of pad holes.

9. The semiconductor package of claim 8, wherein:
the plurality of conductive barrier layers have a first thickness in the vertical direction;
the plurality of uppermost conductive interposer patterns have a second thickness in the vertical direction; and
a ratio of the first thickness to the second thickness is in a range of about 1:1 to about 1:6.

10. The semiconductor package of claim 1, wherein the plurality of interposer redistribution structures further comprise a plurality of interposer seed layers, each of the plurality of interposer seed layers covering a portion of a corresponding conductive interposer pattern of the plurality of conductive interposer patterns and a side surface and a lower surface of a corresponding conductive interposer via of the plurality of conductive interposer vias.

11. A semiconductor package comprising:
a base substrate including a plurality of base redistribution structures sequentially stacked in a vertical direction and a base insulation layer, the plurality of base redistribution structures including a plurality of conductive base patterns and a plurality of conductive base vias;
a semiconductor chip attached on the base substrate by a plurality of chip connection members;
an interposer substrate including a plurality of interposer redistribution structures sequentially stacked in the vertical direction and an interposer insulation layer having an upper surface that includes a plurality of pad holes, the interposer substrate is disposed on the semiconductor chip, the plurality of interposer redistribution structures including a plurality of conductive interposer patterns and a plurality of conductive interposer vias;
a plurality of conductive posts disposed around the semiconductor chip to extend in the vertical direction, the plurality of conductive posts connecting the base substrate with the interposer substrate;
a molding layer disposed between the base substrate and the interposer substrate, the molding layer surrounding the semiconductor chip and the plurality of conductive posts;
a plurality of conductive connection pads respectively disposed on a plurality of uppermost conductive interposer patterns of an uppermost interposer redistribution structure of the plurality of interposer redistribution structures and respectively disposed in the plurality of pad holes; and
a plurality of conductive pad seed layers, each of the plurality of conductive pad seed layers is disposed between a corresponding uppermost conductive interposer pattern of the plurality of uppermost conductive interposer patterns and a corresponding conductive connection pad of the plurality of conductive connection pads, the plurality of conductive pad seed layers respectively covering lower surfaces of the plurality of conductive connection pads,
wherein a side surface and an upper surface of each of the plurality of uppermost conductive interposer patterns and a side surface and an upper surface of each of the plurality of conductive connection pads are exposed by the interposer insulation layer.

12. The semiconductor package of claim 11, wherein:
each of the plurality of pad holes has a tapered shape, wherein a horizontal cross-sectional area of each of the plurality of pad holes narrows progressively towards a bottom surface of each of the plurality of pad holes from an inlet of each of the plurality of pad holes; and
the plurality of uppermost conductive interposer patterns are respectively disposed on the bottom surfaces of the plurality of pad holes.

13. The semiconductor package of claim 11, wherein a plurality of uppermost conductive base patterns of an uppermost base redistribution structure of the plurality of base redistribution structures are disposed on an upper surface of the base insulation layer and are surrounded by the molding layer.

14. The semiconductor package of claim 11, further comprising a plurality of conductive barrier layers, each of the plurality of conductive barrier layers is disposed between a corresponding conductive pad seed layer of the plurality of conductive pad seed layers and a corresponding uppermost conductive interposer pattern of the plurality of uppermost conductive interposer patterns, the plurality of conductive barrier layers respectively covering the upper surfaces of the plurality of uppermost conductive interposer patterns.

15. The semiconductor package of claim 11, wherein the upper surface of the interposer insulation layer is disposed at a height from an upper surface of the base substrate in the vertical direction that is greater than or equal to a height of the upper surfaces of the plurality of conductive connection pads from the upper surface of the base substrate in the vertical direction.

16. The semiconductor package of claim 11, wherein a width of the plurality of conductive connection pads in a first horizontal direction is less than a width of the plurality of uppermost conductive interposer patterns in the first horizontal direction.

17. A semiconductor package comprising:
a first base substrate;
a first semiconductor chip attached on the first base substrate;
a plurality of conductive posts disposed around the first semiconductor chip, on the first base substrate;
an interposer substrate including an interposer redistribution structure having a conductive interposer pattern, a conductive interposer via and an interposer insulation layer, the interposer insulation layer having an upper surface including a pad hole exposing the conductive interposer pattern, the interposer substrate is electrically connected with the first base substrate through the plurality of conductive posts;
a second base substrate on the interposer substrate;
a second semiconductor chip attached on the second base substrate;
a conductive connection pad disposed on the conductive interposer pattern, in the pad hole; and
an external connection terminal disposed on the conductive connection pad, the external connection terminal electrically connecting the interposer substrate with the second base substrate,
wherein an inner sidewall of the pad hole is inclined with respect to an upper surface of the interposer insulation layer, the inner sidewall of the pad hole is spaced apart from the conductive connection pad and the conductive interposer pattern in a first horizontal direction.

18. The semiconductor package of claim 17, wherein:
a width of the conductive connection pad in the first horizontal direction is less than a width of the conductive interposer pattern in the first horizontal direction; and
the external connection terminal is spaced apart from the conductive interposer pattern by the conductive connection pad.

19. The semiconductor package of claim 17, further comprising:
a conductive barrier layer disposed between the conductive interposer pattern and the conductive connection pad, the conductive barrier layer covering an upper surface of the conductive interposer pattern; and
the external connection terminal covers an upper surface of the conductive barrier layer.

20. The semiconductor package of claim 17, wherein an upper surface of the interposer insulation layer is disposed at a height from the interposer substrate in a vertical direction that is greater than or equal to a height of an upper surface of the conductive connection pad from the interposer substrate in the vertical direction.
